(19) United States
(12) Patent Application Publication
(10) Pub. No.: US 2026/0198250 A1
(43) Pub. Date: Jul. 9, 2026

(54) SUBSTRATE HEATING APPARATUS WITH ENHANCED TEMPERATURE UNIFORMITY CHARACTERISTIC

(71) Applicant: MiCo Ceramics Ltd., Anseong-si (KR)

(72) Inventors: Taek Gon KIM, Anseong-si (KR); Jung Chul JIN, Anseong-si (KR)

(21) Appl. No.: 19/551,471

(22) Filed: Feb. 26, 2026

Related U.S. Application Data
(62) Division of application No. 17/822,742, filed on Aug. 26, 2022.

(30) Foreign Application Priority Data
Aug. 30, 2021 (KR) 10-2021-0114650

(51) Int. Cl. H10P 72/00

(52) U.S. Cl. CPC H10P 72/0432; H10P 72/0434

(57) ABSTRACT

The present disclosure discloses a substrate heating apparatus for heating a substrate, wherein the substrate heating apparatus includes: a body including a substrate seating portion on which the substrate is seated, to support the substrate; a first heating element located in an inner region of the body; a second heating element located in an outer region surrounding the inner region; a third heating element configured to transmit current to the second heating element across the inner region of the body; and a connecting member electrically interconnecting the second heating element and the third heating element, wherein the third heating element is made of a molybdenum-tungsten alloy containing molybdenum in a proportion of 40 to 80% and tungsten in a proportion of 20 to 60%.

### CROSS-REFERENCE TO RELATED APPLICATION(S)

This application is a division application of U.S. Patent Application 17/822,742, filed on August 26, 2022, which is based on and claims priority under 35 U.S.C. 119 to Korean Patent Application No. 10-2021-0114650, filed on Aug. 30, 2021, in the Korean Intellectual Property Office, the disclosure of which is herein incorporated by reference in its entirety.

### BACKGROUND OF THE INVENTION

### Field of the Invention

The present disclosure relates to a substrate heating apparatus. More particularly, the present disclosure relates to a substrate heating apparatus that includes a first heating element located in an inner region of the substrate heating apparatus, a second heating element located in an outer region, a third heating element configured to transmit power to the second heating element across the inner region, and a connecting member that electrically connects the second heating element and the third heating element, and is capable of effectively suppressing the occurrence of fine cracks due to thermal expansion and compressive stress caused by high temperature and high pressure applied to the connecting member.

### Description of the Prior Art

In general, in order to manufacture a flat panel display panel or a semiconductor device, a substrate such as a glass substrate, a flexible substrate, or a semiconductor substrate is subjected to processes of sequentially laminating and patterning a series of layers including a dielectric layer and a metal layer thereon. In this case, the series of layers such as the dielectric layer and the metal layer are deposited on a substrate through a process such as chemical vapor deposition (CVD) or physical vapor deposition (PVD).

In this case, in order to uniformly form the layers, the substrate should be heated to a uniform temperature, and a substrate heating apparatus may be used to heat and support the substrate. The substrate heating apparatus may be used for heating a substrate in an etching process of a dielectric layer or a metal layer formed on the substrate, a sintering process of a photo resistor, and the like.

Furthermore, in recent years, the demand for a method for reducing the temperature deviation of the substrate heating apparatus has continued due to the need for finer wiring of semiconductor devices and precise heat treatment of semiconductor substrates. In particular, a substrate heating apparatus has a support portion located in the central region thereof for supporting a body made of ceramic or the like and having a built-in heating element. Thus, due to a problem such as an increase in heat capacity, even if the same amount of heat is supplied to each region of the substrate heating apparatus, a temperature deviation may occur between the regions.

In this regard, a technique was attempted in which, as illustrated in FIG. 1, the substrate heating apparatus is divided into an inner region (the region B in FIG. 1) and an outer region (the region C in FIG. 1) and the heating of the substrate is controlled for each region, thereby reducing the temperature deviation between the inner region (the region B of FIG. 1) and the outer region (the region C in FIG. 1). In this case, however, a problem may arise in that, due to heat generation by a conductor for supplying current to a heating element of the outer region (the region C in FIG. 1), a specific region (the region A in FIG. 1) corresponding to the conductor is overheated. For example, FIG. 2 illustrates a problem arising in that, due to heat generation from a conductor that transmits power to a heating element in the outer region across the inner region, a specific region (the region A in FIG. 2) corresponding to the conductor is overheated.

The body of the substrate heating apparatus is usually made of ceramic such as aluminum nitride (AlN), whereas the connector or the like for connecting the heating element is made of a metal such as molybdenum (Mo). In the process of manufacturing the substrate heating apparatus, after disposing the heating element, the connector and the like at predetermined positions in a preform of the body made of ceramic such as aluminum nitride (AlN), and then the ceramic is sintered by applying high pressure under a high-temperature (e.g., about 1,800 degrees C) environment to fabricate the body.

However, in the sintering process, while the high pressure is applied in the high temperature environment, since thermal stress due to a difference in coefficient of thermal expansion (CTE) between the ceramic of the body and the metal material of the connector and compressive stress due to the high pressure are induced in the body, fine cracks may occur in the body. In addition, the durability of the substrate heating apparatus may be deteriorated and the service life of the substrate heating apparatus may be shortened due to diffusion of the cracks according to the use of the substrate heating apparatus.

Accordingly, there are demands for measures to: alleviate or prevent the problem of overheating in a specific region due to heat generation from the conductor supplying current to the heating element in the outer region while controlling the heating by dividing the substrate heating apparatus into the inner region and the outer region; to prevent the occurrence of fine cracks in the body by suppressing the generation of thermal stress due to the difference in thermal expansion coefficient between the metal material of the connector and the ceramic of the body and compressive stress caused by the applied high pressure in the sintering process or the like in which high temperature and high pressure are applied during the manufacturing process of the substrate heating apparatus; to effectively prevent deterioration of durability and shortening of service life of the substrate heating apparatus. However, appropriate measures have not yet been proposed.

### Prior Art Document

### Patent Document

### Japanese Patent Laid-Open No. 2001-102157 (published on April 13, 2001)

### SUMMARY OF THE INVENTION

The present disclosure was made to solve the problems of the prior art described above, and provides a substrate heating apparatus in which, while the substrate heating apparatus is divided into a plurality of regions including an inner region and an outer region to control heating for each region, it is possible to prevent a specific region from being overheated due to heat generation by a conductor that supplies current to a heating element of the outer region.

In addition, the present disclosure provides a substrate heating apparatus in which, while the substrate heating apparatus is divided into a plurality of regions including an inner region, an outer region, and an intermediate region crossing the inner region and is heated for each region, it is possible to minimize non-uniformity in substrate heating due to heat generation by the conductor in the intermediate region.

In addition, the present disclosure provides a structure capable of improving thermal and structural stability in a connecting structure between the heating element in the outer region and the conductor supplying current thereto.

Furthermore, the present disclosure provides a substrate heating apparatus in which, by suppressing the generation of thermal stress due to the difference in thermal expansion coefficient between the metal material of the connector and the ceramic material of the body and the generation of compressive stress due to the applied high pressure in the sintering process or the like in which high temperature and high pressure are applied in the process of manufacturing the substrate heating apparatus, it is possible to prevent the occurrence of fine cracks in the body and is also possible to effectively prevent deterioration in durability and shortening of service life of the substrate heating apparatus.

In view of the foregoing, a substrate heating apparatus for heating a substrate according to an aspect of the present disclosure includes: a body including a substrate seating portion on which the substrate is seated, to support the substrate; a first heating element located in an inner region of the body; a second heating element located in an outer region surrounding the inner region; a third heating element configured to transmit current to the second heating element across the inner region of the body; and a connecting member electrically interconnecting the second heating element and the third heating element, wherein the third heating element is made of a molybdenum-tungsten alloy containing molybdenum in a proportion of 40% to 80% and tungsten in a proportion of 20% to 60%.

The connecting member may be implemented in a partially spherical shape obtained by removing, from a spherical shape, a portion below a first plane spaced apart by a predetermined distance downward from a center point of the spherical shape, and the first plane may be disposed in parallel to the substrate seating portion.

The connecting member may be implemented in a oval shape obtained by vertically contracting a spherical shape, and may be disposed such that a vertical axis of the oval shape is perpendicular to the substrate seating portion.

The connecting member may be implemented in a cylindrical shape, and is disposed such that a longitudinal axis of the cylindrical shape is perpendicular to the substrate seating portion, and openings into which the second heating element and the third heating element are fixedly inserted, respectively, may be vertically provided in a side portion of the cylindrical shape in a direction perpendicular to the longitudinal axis.

The connecting member may be implemented in a cylindrical shape, and is disposed such that a longitudinal axis of the cylindrical shape is parallel to the substrate seating portion, and openings into which the second heating element and the third heating element are fixedly inserted, respectively, may be provided in opposite flat surfaces of the cylindrical shape to face each other.

At least one of the first heating element, the second heating element and the connecting member may be made of molybdenum-tungsten alloy containing molybdenum and tungsten.

At least one of the first heating element, the second heating element and the connecting member may be made of molybdenum-tungsten alloy containing molybdenum in a proportion of 40% to 80% and tungsten in a proportion of 20% to 60%.

The connecting member may have been subjected to a heat treatment process including an annealing process.

The annealing process may be performed at a temperature selected within a range between recrystallization temperature of molybdenum and recrystallization temperature of tungsten.

The heat treatment process may include a rapid cooling process of rapidly cooling the connecting member in a temperature range in which a sigma phase is generated in the molybdenum.

The substrate heating apparatus may further include a heating element connector connected to an end of the first heating element to transmit power supplied from a power supply, wherein the heating element connector may be made of a molybdenum-tungsten alloy containing molybdenum and tungsten.

The heating element connector may have been made of molybdenum-tungsten alloy containing molybdenum and tungsten.

The heating element connector may be made of molybdenum-tungsten alloy containing molybdenum in a proportion of 40% to 80% and tungsten in a proportion of 20% to 60%.

The substrate heating apparatus may further include a high-frequency electrode unit to which high-frequency waves are applied to generate plasma and a high-frequency connector connected to an end of the high-frequency electrode unit to transmit high-frequency waves supplied from a high-frequency wave supply unit, wherein at least one of the high-frequency electrode unit and the high-frequency connector is made of a molybdenum-tungsten alloy containing molybdenum and tungsten.

At least one of the high-frequency electrode unit and the high-frequency connector may be made of molybdenum-tungsten alloy contains molybdenum in a proportion of 40% to 80% and tungsten in a proportion of 20% to 60%.

### Advantageous Effect

In the present disclosure, the substrate heating apparatus is divided into a plurality of regions including an inner region and an outer region, and, while controlling heating for each region, the diameter of the wire of the third heating element, which supplies current to the second heating element located in the outer region, is set to be thicker than the diameter of the wire of the second heating element. As a result, it is possible to suppress overheating of a specific region due to heat generation by the third heating element.

In the present disclosure, the substrate heating apparatus is divided into a plurality of regions including an inner region, an outer region, and an intermediate region crossing the inner region, and while heating the substrate heating apparatus for each region, the sum of the calorific value generated by the third heating element in the intermediate region and the calorific value generated by the second heating element is controlled to be within a predetermined range. As a result, it is possible to minimize the non-uniformity of heating a substrate due to heat generation by the conductor in the intermediate region.

In the present disclosure, the second heating element and the third heating element are interconnected by using a connecting member made of the same material as the second heating element located in the outer region and the third heating element in the intermediate region. As a result, it is possible to maintain thermal and structural stability of the substrate heating apparatus in spite of temperature changes due to heating in the process of manufacturing the substrate heating apparatus and during a substrate processing process.

Furthermore, in the present disclosure, by suppressing the generation of thermal stress due to the difference in thermal expansion coefficient between the metal material of the connector or the like and the ceramic material of the body and the generation of compressive stress due to the applied high pressure in the sintering process or the like in which high temperature and high pressure are applied in the process of manufacturing the substrate heating apparatus, it is possible to prevent the occurrence of fine cracks in the body and to effectively prevent deterioration in durability and shortening of service life of the substrate heating apparatus.

### BRIEF DESCRIPTION OF THE DRAWINGS

The accompanying drawings, which are included as a part of the detailed description to help the understanding of the present disclosure, provide embodiments of the present disclosure and illustrate the technical spirit of the present disclosure together with the detailed description, in which:

FIG. 1 is a top view of a substrate heating apparatus according to the related art;

FIG. 2 is a view illustrating a case in which a specific region is overheated due to non-uniform heating in a substrate heating apparatus according to the related art;

FIGS. 3A to 3C are exemplary views illustrating a structure of a substrate heating apparatus according to an embodiment of the present disclosure;

FIG. 4 is a table showing changes in calorific values generated by a third heating element as an embodiment of the present disclosure depending on the wire diameter thereof;

FIGS. 5A and 5B are views illustrating a case in which overheating in a specific area is eliminated in the substrate heating apparatus according to an embodiment of the present disclosure;

FIGS. 6A to 6D are views each illustrating a structure of a connecting member that interconnects a second heating element and a third heating element in the substrate heating apparatus according to an embodiment of the present disclosure;

FIG. 7 is a view illustrating a case in which a deviation between the calorific value in an intermediate region and the calorific value in a region symmetrical with the intermediate region is reduced in the substrate heating apparatus according to an embodiment of the present disclosure;

FIG. 8 is a view illustrating a case in which a deviation between the calorific value in an intermediate region and the calorific value in a region perpendicular to the intermediate region is reduced in the substrate heating apparatus according to an embodiment of the present disclosure;

FIG. 9 is a view exemplifying the configuration of a substrate heating apparatus according to an embodiment of the disclosure;

FIGS. 10A to 10C, 11, 12 and 13A to 13C are views exemplifying shapes of the connecting member according to an embodiment of the present disclosure;

FIGS. 14 to 18 are views illustrating connecting members and connectors in the substrate heating apparatus according to an embodiment of the present disclosure; and

FIGS. 19A, 19B and 20 are views illustrating heat treatment performed on connecting members and connectors in the substrate heating apparatus according to an embodiment of the present disclosure.

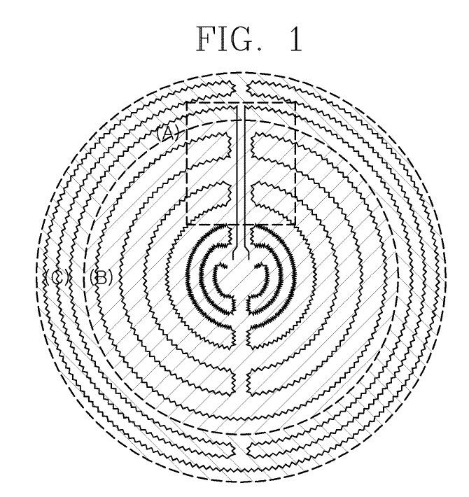

### DETAILED DESCRIPTION OF THE EXEMPLARY EMBODIMENTS

The present disclosure may be variously modified and may include various embodiments. Hereinafter, specific embodiments will be described in detail with reference to the accompanying drawings.

In describing the present disclosure, when it is determined that a detailed description of a related known technology may obscure the gist of the present disclosure, the detailed description thereof will be omitted.

Terms such as first, second, and the like may be used to describe various components, but the components are not limited by the terms, and these terms are used only for the purpose of distinguishing one component from another.

Hereinafter, exemplary embodiments of a substrate heating apparatus according to the present disclosure will be described in detail with reference to the accompanying drawings.

As described above, when the region of the substrate heating apparatus is divided into a plurality of regions including an inner region and an outer region and heated for each region in order to increase the thermal uniformity of the substrate heating apparatus, there may be a problem in that a specific region is overheated due to heat generation from a conductor for transmitting power to a heating element of the outer region across the internal region.

In this regard, the present disclosure discloses a substrate heating apparatus including: a first heating element located in an inner region of the substrate heating apparatus; a second heating element located in the outer region; and a third heating element configured to transmit power to the second heating element across the inner region, wherein the diameter of the wire constituting the third heating element is thicker than the diameter of the wire constituting the second heating element so that the generation of an overheating region due to heat generation by the third heating element can be suppressed.

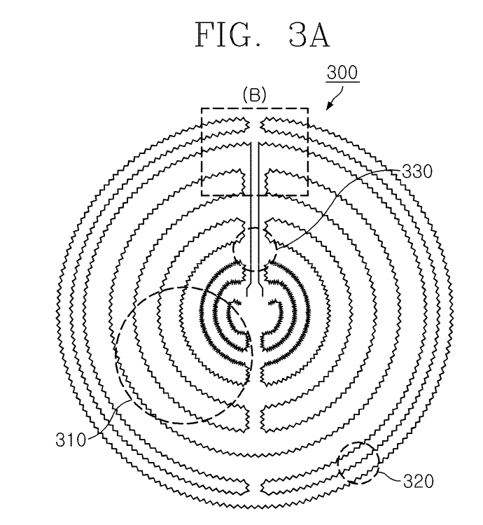

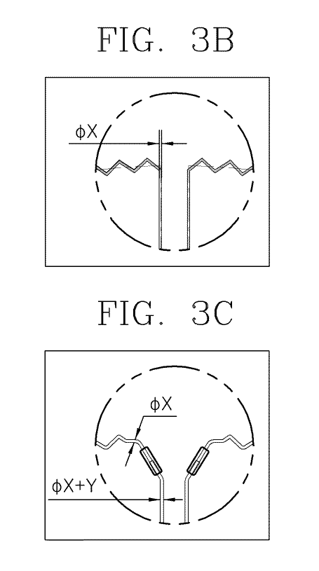

FIGS. 3A to 3C illustrate a structure 300 of a substrate heating apparatus according to an embodiment of the present disclosure. As can be seen from FIGS. 3A to 3C, the substrate heating apparatus 300 according to an embodiment of the present disclosure includes: a body (not illustrated) that supports a substrate; a first heating element 310 located in an inner region of the body; a second heating element 320 located in an outer region surrounding the inner region; and a third heating element 330 that transmits current to the second heating element 320 across the inner region of the body, wherein the diameter of the wire constituting the third heating element 330 is thicker than the diameter of the wire constituting the second heating element 320, so that the resistance value of the third heating element 330 is lowered and heat generation in the heating element 330 is suppressed so that it is possible to prevent overheating of a specific region due to the heat generation of the third heating element 330.

In this case, a substrate, such as a glass substrate, a flexible substrate, or a semiconductor substrate, is seated on the substrate heating apparatus 300 and subjected to processes for laminating a series of layers including a dielectric layer and a metal layer thereon by a process such as chemical vapor deposition (CVD) or physical vapor deposition (PVD) and patterning the layers. In this case, the substrate heating apparatus 300 uniformly heats the substrate to a predetermined temperature required for the processes.

The body (not illustrated) of the substrate heating apparatus 300 may be made of ceramic or metal depending on the use of the substrate heating apparatus or the process in which the substrate heating apparatus is used, and a heating element for heating a substrate together with a high-frequency electrode (not illustrated) used in a plasma process or the like may be included in the body. In addition, a plurality of pinholes (not illustrated) may be formed in the substrate heating apparatus 300 so that lift pins for seating a substrate on the top surface of the body or unloading the substrate to the exterior are movable through the pinholes.

For stability in a high-temperature process or the like, the body of the substrate heating apparatus 300 may be made of a ceramic material, and the ceramic material, which may be used at this time, may be Al₂O₃, Y₂O₃, Al₂O₃/Y₂O₃, ZrO₂, AlC, TiN, AlN, TiC, MgO, CaO, CeO₂, TiO₂, BₓC_{y}, BN, SiO₂, SiC, YAG, Mullite, AlF₃, or the like, and two or more of the ceramic materials may be used in combination.

The heating element may be formed of tungsten (W), molybdenum (Mo), silver (Ag), gold (Au), platinum (Pt), niobium (Nb), titanium (Ti), or an alloy thereof.

As can be seen in FIG. 3B, since the second heating element 320 and the third heating element 330 are typically made of a single wire of the same diameter, it is somewhat easy to configure the substrate heating apparatus in a structure in which the substrate heating apparatus is divided into a plurality of regions to be heated for each region. However, in this case, when power is applied to heat the second heating element 320 in the outer region, a problem may arise in that heat is also generated in the third heating element 330 in the same manner as in the second heating element 320, and the intermediate region in which the third heating element 330 is located is overheated.

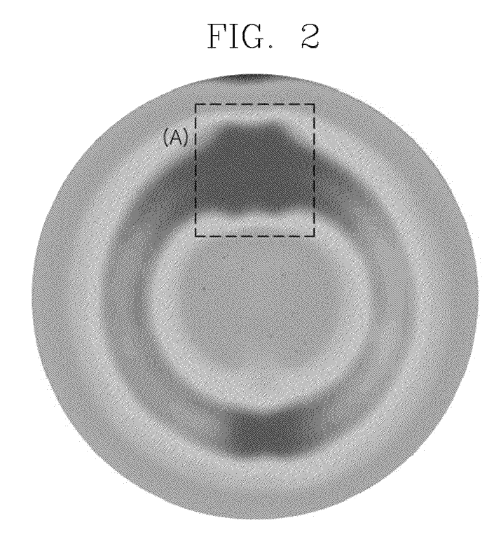

In particular, since the calorific value by the first heating element 310 close to the intermediate region is added to the calorific value by the third heating element 330, the intermediate region may be further heated. As a result, a problem may arise in that, as described above with reference to FIG. 2, a specific region is overheated and thermal uniformity is greatly deteriorated.

In this regard, in order to reduce the effect of heat generation from the first heating element 310, a measure of separating the first heating element 310 from the third heating element 330 may be considered. However, in this case, depending on the power application state for each region, the calorific value in the intermediate region where the third heating element 330 is located may be significantly different from the calorific value in the region that is symmetrical with the intermediate region with respect to the center point of the body. Thus, in some cases, the thermal uniformity of the substrate heating apparatus may be deteriorated.

Therefore, it is preferable that the structure of the first heating element 310 in the intermediate region and the structure of the first heating element 310 in the region symmetrically corresponding to the intermediate region have the same symmetrical structure if possible, and even if it is not possible to configure the symmetrical structure for wire-wrapping or the like of the third heating element 330, it is preferable to configure the structures as similar as possible.

Accordingly, reducing the calorific value in the third heating element 330 while maintaining the symmetrical structure of the first heating element 310 as much as possible may be a more preferable approach. Accordingly, in the present disclosure, as can be seen in FIG. 3C, the diameter ΦX+Y of the wire constituting the third heating element 330 is increased to be larger than the diameter ΦX of the wire constituting the second heating element to reduce the resistance value, thereby suppressing heat generation by the third heating element 330.

In addition, in the substrate heating apparatus 300 according to an embodiment of the present disclosure, it is preferable to reduce the effect of overlapping the heat generation by the first heating element 310 and the heat generation by the third heating element 330 by preventing the first heating element 310 from being located in the intermediate region in which the third heating element 330 is located, so that the first heating element 310 and the third heating element 330 are disposed to be spaced apart from each other, rather than being disposed to overlap each other.

The substrate heating apparatus 300 according to an embodiment of the present disclosure does not necessarily have to be configured by dividing the substrate heating apparatus into only two regions of the inner region and the outer region, as illustrated in FIG. 3A, and the substrate heating apparatus may include a plurality of regions by further including one or more regions in addition to the inner region and the outer region.

In addition, the first heating element 310, the second heating element 320, and the third heating element 330 are configured in a symmetrical shape with reference to the central axis of the intermediate region passing through the central point of the body. As a result, it is possible to make the substrate heating apparatus 300 according to an embodiment of the present disclosure have a symmetrical thermal distribution with reference to the central axis, and furthermore, it is possible to further improve the thermal uniformity of the substrate heating apparatus 300.

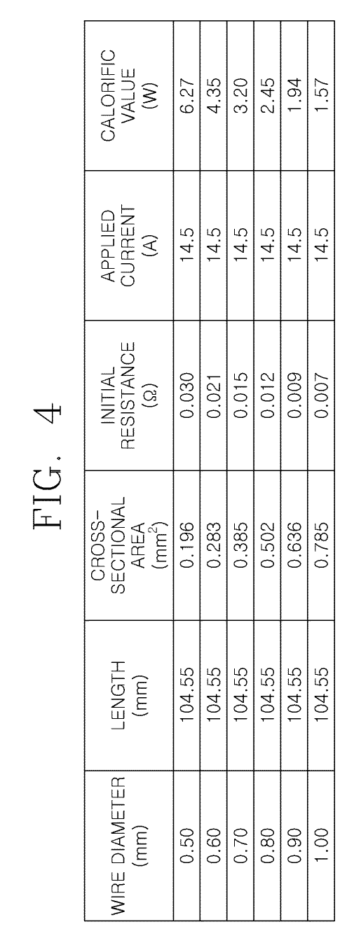

FIG. 4 is a table showing the resistance values and calorific values of the wire constituting the third heating element according to an embodiment of the present disclosure that are calculated while varying the diameter of the wire. As can be seen in FIG. 4, when the diameter of the wire constituting the third heating element is 0.50 mm, the resistance value of the wire is 0.030 Ω, and when the current of 14.5 A is applied to the wire, the wire exhibits the calorific value of 6.27 W.

In contrast, when the diameter of the wire constituting the third heating element is 1.00 mm, the resistance value of the wire is 0.007 Ω, and when the current of 14.5 A is applied to the wire, the wire exhibits the calorific value of 1.57 W. Thus, it can be seen that as the diameter of the wire doubles from 0.50 mm to 1.00 mm, the resistance value and the calorific value each fall to about 1/4 the original level.

Similarly, it can be seen that, as the diameter of the wire constituting the third heating element increases by about 1.4 times from 0.5 mm to 0.70 mm, the resistance value and the calorific value each fall to about 1/2 level.

Therefore, by increasing the diameter of the wire, it is possible to reduce the calorific value generated by the wire. However, since it is not possible to increase the diameter of the wire indefinitely, it is preferable to adjust the calorific value generated in the intermediate region in which the third heating element 330 is located to be close to the calorific value generated in the other regions in consideration of the diameter of the wire, the spacing between the wire, and the calorific value generated by the first heating element.

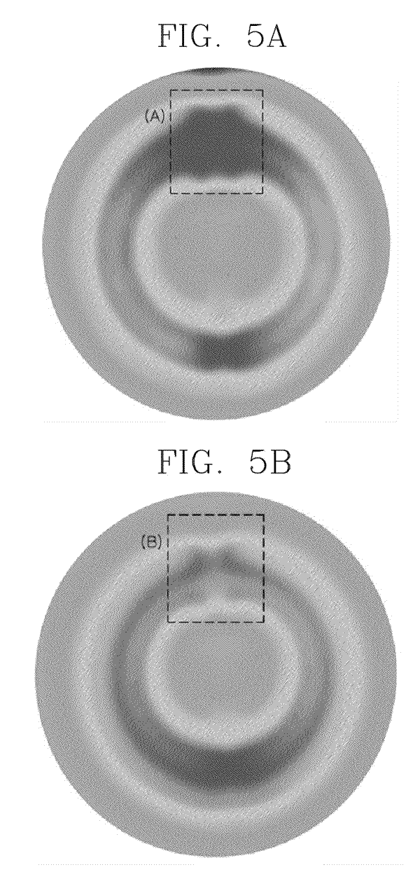

FIGS. 5A and 5B illustrate a case in which overheating in a specific area is suppressed in the substrate heating apparatus 300 according to an embodiment of the present disclosure so that thermal uniformity is improved. As can be seen in FIG. 5A, when the heat generation by the third heating element 330 in the intermediate region is not properly suppressed, the calorific value is concentrated to the intermediate region and thus overheating may occur. However, it is shown that, in the substrate heating apparatus 300 according to an embodiment of the present disclosure, by setting the diameter of the wire constituting the third heating element 330 to be thicker than the diameter of the wire constituting the second heating element 320, it is possible to effectively suppress the occurrence of overheating in the intermediate region by reducing the resistance value of the third heating element 330 and suppressing the heat generation by the third heating element 330.

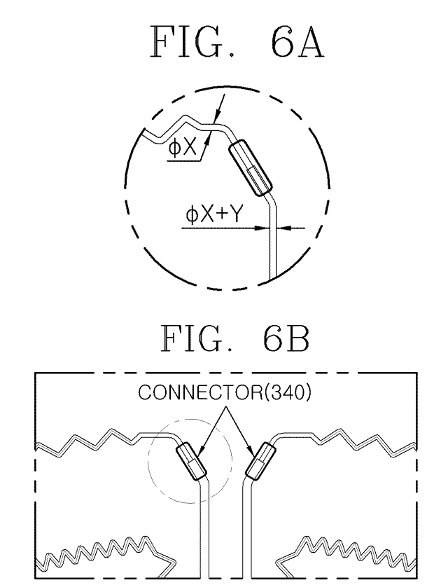

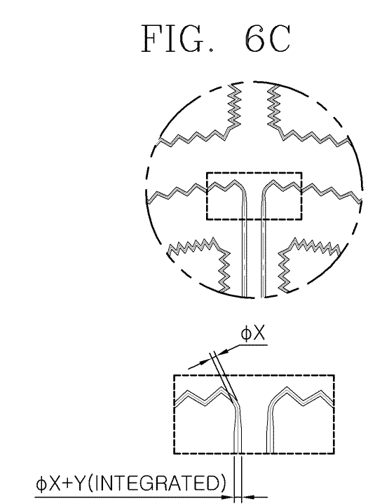

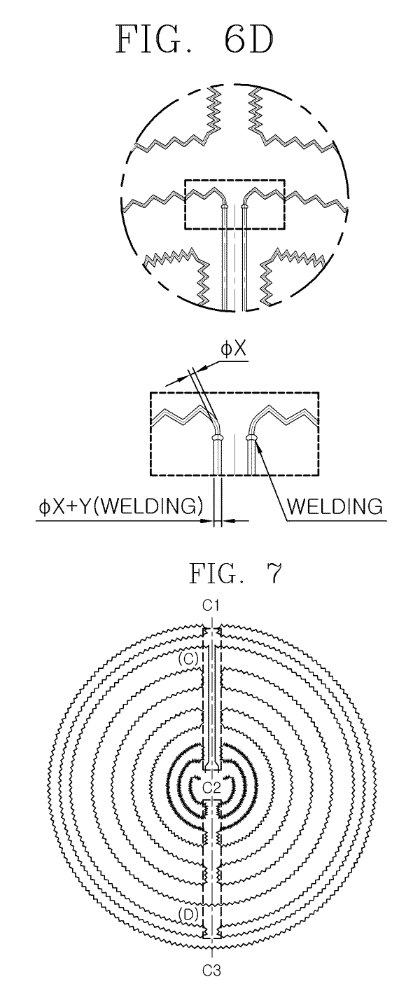

FIGS. 6A to 6D are views illustrating structures of connecting members interconnecting the second heating element 320 and the third heating element 330 in the substrate heating apparatus 300 according to an embodiment of the present disclosure. As can be seen in FIG. 6A, as an embodiment of the present disclosure, the wire of the second heating element 320 has a diameter of ΦX, and the wire of the third heating element 330 has a diameter of ΦX+Y. Thus, the second heating element and the third heating element may be made of separate wires having different diameters. Therefore, as can be seen in FIG. 6B, the second heating element 320 and the third heating element 330 may be interconnected by using connecting members 340.

In this case, the connecting members 340 may each include openings into which wires constituting the second heating element 320 and the third heating element 330 and having different diameters are press-fitted and fixed. In addition, all of the second heating element 320, the third heating element 330, and the connecting members 340 may be made of the same material.

Accordingly, in the second heating element 320, the third heating element 330, and the connecting members 340, coupling structures can be stably maintained even in a high-temperature environment or the like in the process of manufacturing the substrate heating apparatus 300 according to an embodiment of the present disclosure, such as ceramic sintering, or in a substrate processing process such as chemical vapor deposition (CVD) on a substrate.

The connecting members 340 do not always have to be used in the substrate heating apparatus 300 according to an embodiment of the present disclosure. As a more specific example, as can be seen in FIG. 6C, the second heating element 320 and the third heating element 320 may be configured with a single wire, and the connection portions of the second heating element 320 and the third heating element 330 may have a tapered shape. This makes it possible to further improve thermal and structural stability in the connection portion between the second heating element 320 and the third heating element 330, so that the connection structure can be more stably maintained even at a very high temperature or repeated thermal environment changes. Alternatively, as shown in FIG. 6D, the connection portions of the second heating element 320 and the third heating element 330 may be joined by using welding or the like.

FIG. 7 illustrates a structure for reducing the deviation between the calorific value generated in the intermediate region (the region C in FIG. 7) and the calorific value generated in the symmetric region (the region D in FIG. 7) of the substrate heating apparatus 300 as an embodiment of the present disclosure. That is, with respect to a symmetrical region that is symmetrical with the intermediate region with respect to the central point of the body in the substrate heating apparatus 300, it is possible to make the average surface temperature value due to the heat generation of the first heating element 310 and the third heating element 330 on the central axis (C1-C2 in FIG. 7) of the intermediate region that passes through the central point of the body substantially equal to the average surface temperature value due to the heat generation of the first heating element 310 on the central axis (C2-C3 in FIG. 7) of the symmetrical region that passes through the central point of the body. To this end, it is possible to adjust the diameter of the third heating element 330 around the central axis in the intermediate region, the separation distance between the wires of the third heating elements 330, the separation distance between the third heating element 330 and the first heating element 310, and the like.

Accordingly, by making the average value of the temperature at the central axis of the intermediate region and the surface temperature at the central axis of the symmetric region equal to each other, it is possible to improve the thermal uniformity of the substrate heating apparatus 300 according to the embodiment of the present disclosure.

As another embodiment of the present disclosure, by making the difference between the maximum value and the minimum value of the surface temperature due to the heat generation of the first heating element 310 and the third heating element 330 on the central axis (C1-C2 in FIG. 7) of the intermediate region (the region C in FIG. 7) that passes through the central point of the body smaller than or equal to the difference between the maximum value and the minimum value of the surface temperature due to the heat generation of the first heating element 310 on the central axis (C2-C3 in FIG. 7) of the symmetrical region (the region D in FIG. 7) that passes through the central point of the body, it is also possible to improve the thermal uniformity of the substrate heating apparatus 300 according to an embodiment of the present disclosure.

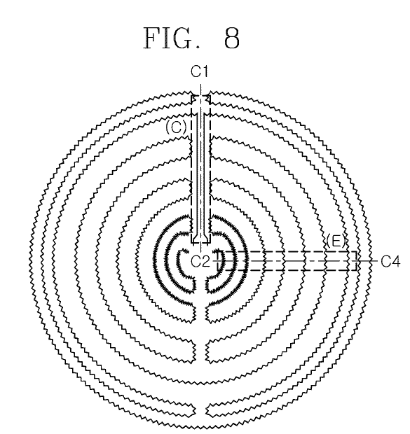

FIG. 8 illustrates a structure for reducing the deviation between the calorific value generated in the intermediate region (the region C in FIG. 8) of the substrate heating apparatus 300 and the calorific value generated in a region (the region E in FIG. 8) perpendicular to the intermediate region as an embodiment of the present disclosure. First, with respect to the intermediate region and the region perpendicular to the intermediate region in the substrate heating apparatus 300, it is possible to make the average surface temperature value due to the heat generation of the first heating element 310 and the third heating element 330 on the central axis (C1-C2 in FIG. 8) of the intermediate region that passes through the central point of the body substantially equal to the average surface temperature value due to the heat generation of the first heating element 310 on the central axis (C2-C4 in FIG. 8) of the region perpendicular to the intermediate region that passes through the central point of the body. To this end, it is possible to adjust the diameter of the third heating element 330 around the central axis in the intermediate region, the separation distance between the wires of the third heating elements 330, the separation distance between the third heating element 330 and the first heating element 310, and the like.

Accordingly, by making the average value of the temperature at the central axis of the intermediate region and the surface temperature at the central axis of the region perpendicular to the intermediate region equal to each other, it is possible to improve the thermal uniformity of the substrate heating apparatus 300 according to the embodiment of the present disclosure.

As another embodiment of the present disclosure, by making the difference between the maximum value and the minimum value of the surface temperature due to the heat generation of the first heating element 310 and the third heating element 330 on the central axis (C1-C2 in FIG. 8) of the intermediate region (the region C in FIG. 8) that passes through the central point of the body, smaller than or equal to the difference between the maximum value and the minimum value of the surface temperature due to the heat generation of the first heating element 310 on the central axis (C2-C4 in FIG. 8) of the region perpendicular to the intermediate region (the region E in FIG. 8), it is also possible to improve the thermal uniformity of the substrate heating apparatus 300 according to an embodiment of the present disclosure.

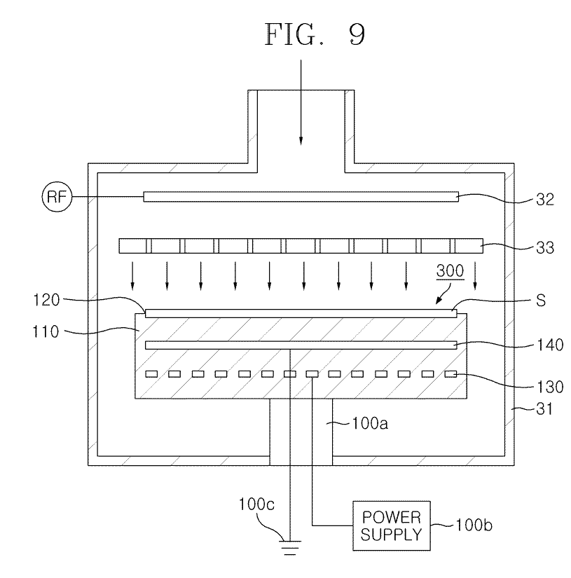

FIG. 9 exemplifies the configuration of a substrate heating apparatus 300 according to an embodiment of the present disclosure. As can be seen in FIG. 9, the substrate heating apparatus 300 according to an embodiment of the present disclosure is a substrate heating apparatus 300 that heats a substrate S, wherein the substrate heating apparatus 300 may include a body 110 including a substrate seating part 120, on which the substrate W is seated, to support the substrate W, and a heating unit 130 built in a lower portion of the body 110 to heat the substrate W. The heating unit 130 may include a first heating element 310 located in an inner region of the body 110, a second heating element 320 located in an outer region surrounding the inner region, and a third heating element 330 configured to transmit current to the second heating element 320 across the inner region of the body 110. In addition, a connecting member 340 that electrically interconnects the second heating element 320 and the third heating element 330 may be further included.

Furthermore, as can be seen in FIG. 9, the substrate heating apparatus 300 according to an embodiment of the present disclosure may include a support 110 that supports the body 110, a power supply 100b that supplies power to the heating unit 130, and a ground unit 100c for grounding, and may be provided with a high-frequency electrode unit 140 to which high-frequency waves for plasma formation is applied.

In addition, as can be seen in FIG. 9, the substrate heating apparatus 300 according to an embodiment of the present disclosure may be disposed inside the chamber 31 to perform a process, and the chamber 31 may be provided with a plasma electrode 32, a shower head 33, and the like.

As described above with reference to FIGS. 3A, 3B and FIGS. 6A to 6D, in the substrate heating apparatus 300 according to an embodiment of the present disclosure, a connecting member 340 used for electrically interconnecting the second heating element 320 and the third heating element 330 is typically made of a metal such as molybdenum (Mo) like the second heating element 320 and the third heating element 330, but the body 110 of the substrate heating apparatus 300 is typically made of ceramic such as aluminum nitride (AlN).

At this time, in the process of manufacturing the substrate heating apparatus 300, the second heating element 320, the third heating element 330, and the connecting member 340, and the like are placed at a predetermined position within a preform of the body 110 made of ceramic such as aluminum nitride (AlN), and then the ceramic is sintered while applying a high pressure in a high-temperature (e.g., about 1,800 degrees C) environment to manufacture the substrate heating apparatus 300.

However, since high pressure is applied in a high-temperature environment in the sintering process, thermal stress due to a difference in coefficient of thermal expansion (CTE) between the ceramic constituting the body 110 and the metal material of the connecting member 340 and the compressive stress due to the high pressure, fine cracks may occur in the ceramic region of the body 110.

Furthermore, the use of the substrate heating apparatus 300 may result in deterioration of durability and shortening of the service life of the substrate heating apparatus 300 due to diffusion of the fine cracks.

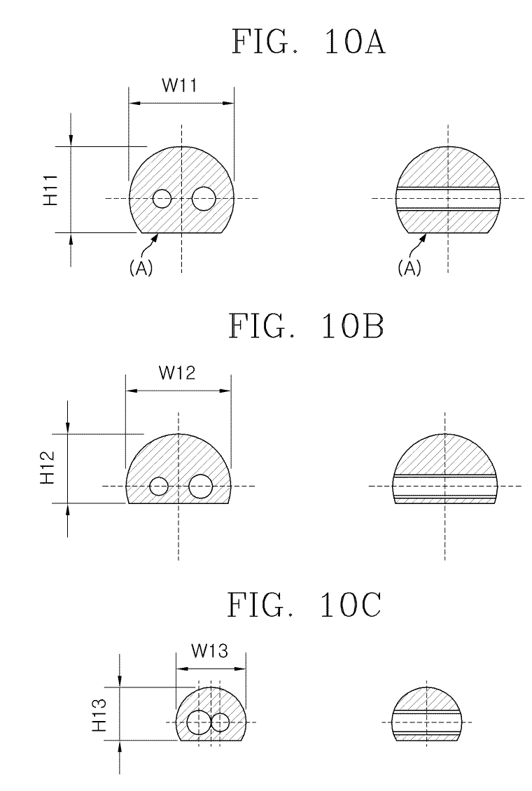

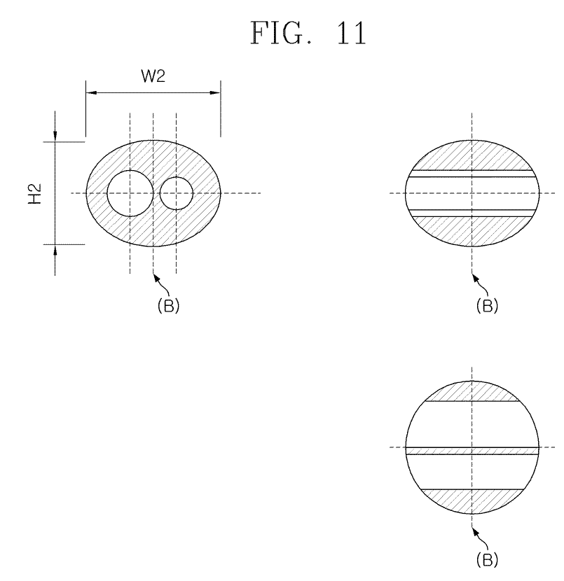

In this regard, in the substrate heating apparatus 300 according to an embodiment of the present disclosure, as can be seen in FIGS. 10A to 10C, the connecting member 340 may be configured in a partially spherical shape obtained by removing, from a spherical shape, a portion under a first plane (e.g., the plane A in FIG. 10A) spaced apart by a predetermined distance downward from the center point of the spherical shape of the first plane. At this time, the first plane of the connecting member 340 may be disposed in parallel to the substrate seating portion 120.

Accordingly, in the substrate heating apparatus 300 according to an embodiment of the present disclosure, since compressive stress is dispersed due to the partially spherical shape of the connecting member 340 and the height of the connecting member 340 is reduced by removing the predetermined downward portion as described above, it is possible to reduce the effect of stress due to high pressure applied from the upper side, thereby suppressing the occurrence of fine cracks.

Furthermore, by removing the predetermined downward portion as described above, it is possible to reduce the volume of the connecting member 340, thereby suppressing the generation of stress due to thermal expansion in a high-temperature environment.

At this time, as can be seen in FIG. 10A, the connecting member 340 may have a structure in which the height (e.g., H11 in FIG. 10A) is smaller than the width (W11 in FIG. 10A).

In addition, in the present disclosure, as can be seen in FIGS. 10A to 10C, by reducing the width (W11 → W12 → W13) and height (H11 → H12 → H13) of the partial spherical shape, it is possible to suppress the generation of thermal stress due to thermal expansion by reducing the volume of the connecting member 340, and at the same time, due to the reduction of the height, it is also possible to prevent the occurrence of fine cracks by suppressing the generation of compressive stress.

In addition, in the substrate heating apparatus 300 according to an embodiment of the present disclosure, as can be seen in FIG. 11, the connecting member 340 may be configured in a oval shape obtained by vertically contracting a spherical shape. In this case, the connecting member 340 may be disposed such that the vertical axis of the oval shape (e.g., (B) in FIG. 11) is perpendicular to the substrate seating portion 120.

Accordingly, in the substrate heating apparatus 300 according to an embodiment of the present disclosure, since compressive stress is dispersed due to the oval shape of the connecting member 340, and the height of the connecting member 340 is reduced due to the vertically contracted oval shape as described above, it is possible to reduce the effect of stress due to high pressure applied from the upper side, thereby suppressing the occurrence of fine cracks.

Furthermore, due to the vertically contract shape as described above, it is possible to reduce the volume of the connecting member 340, thereby suppressing the generation of stress due to thermal expansion in a high-temperature environment so that the occurrence of fine cracks can also be prevented.

At this time, as can be seen in FIG. 11, the connecting member 340 may have a structure in which the height (e.g., H2 in FIG. 11) is smaller than the width (W2 in FIG. 11).

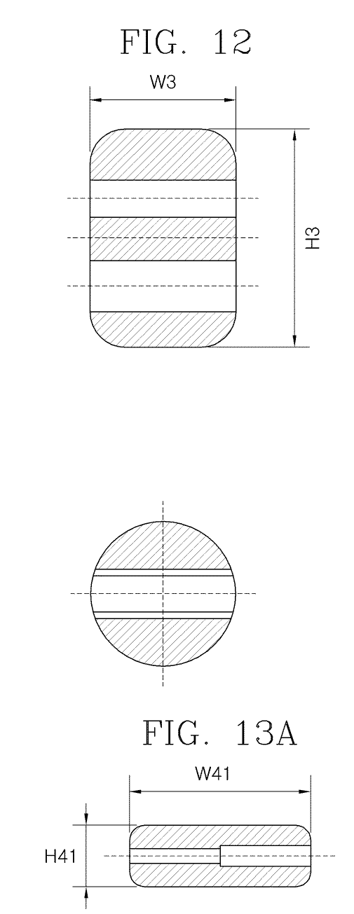

In addition, in the substrate heating apparatus 300 according to an embodiment of the present disclosure, as can be seen in FIG. 12, the connecting member 340 may be implemented in a cylindrical shape, and may be disposed such that the longitudinal axis of the cylindrical shape is perpendicular to the substrate seating portion 120.

Accordingly, in the substrate heating apparatus 300 according to an embodiment of the present disclosure, it is possible to reduce the volume of the connecting member 340 to suppress the generation of stress due to thermal expansion in a high-temperature environment, thereby preventing the occurrence of fine cracks.

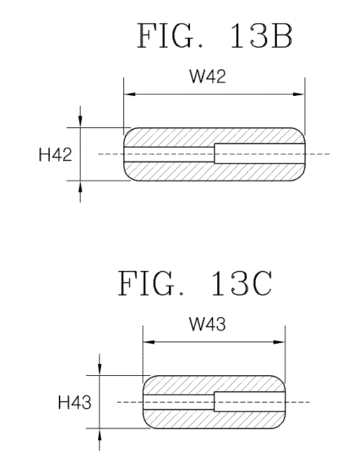

In addition, in the substrate heating apparatus 300 according to an embodiment of the present disclosure, as can be seen in FIGS. 13A to 13C, the connecting member 340 is implemented in a cylindrical shape and may be disposed such that the longitudinal axis of the cylindrical shape is parallel to the substrate seating portion 120. The substrate heating apparatus 300 may include openings into which the second heating element 320 and the third heating element 330 are fixedly inserted, respectively, and which are provided in the opposite flat surfaces of the cylindrical shape to face each other.

This makes it possible to lower the height of the connecting member 340 or reduce the volume of the connecting member 340 (see, e.g., FIGS. 13B and 13C in comparison to FIG. 13A) in the substrate heating apparatus 300 according to an embodiment of the present disclosure. Accordingly, it is possible to prevent the occurrence of fine cracks by suppressing the generation of stress due to thermal expansion or compressive stress in a high-temperature and high-pressure environment.

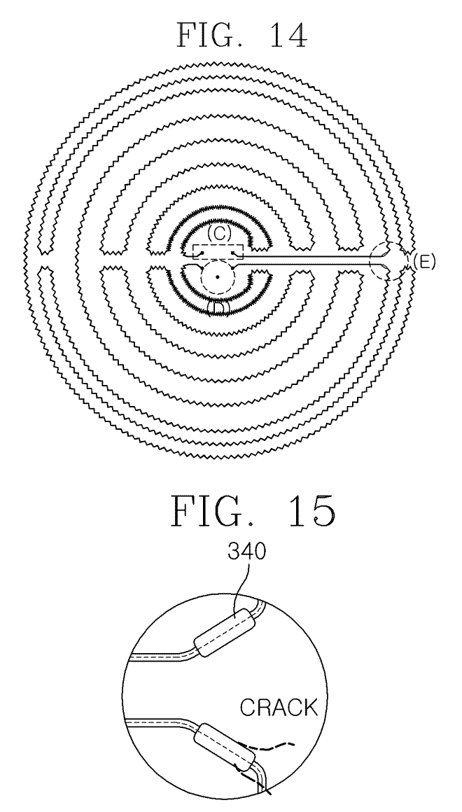

In the substrate heating apparatus 300 according to an embodiment of the present disclosure, the connecting member 340 may be made of a molybdenum-tungsten alloy containing molybdenum (Mo) and tungsten (W) (e.g., located at (E) in FIG. 14).

The substrate heating apparatus 300 according to an embodiment of the present disclosure may include a heating element connector (not illustrated) that is connected to the end of the first heating element 310 and transmits power supplied from the power supply 100b. The heating element connector (not illustrated) may also be made of a molybdenum-tungsten alloy containing molybdenum (Mo) and tungsten (W) (located at (C) in FIG. 14).

As can be seen in FIG. 9, the substrate heating apparatus 300 according to an embodiment of the present disclosure may include a high-frequency electrode unit 140 to which high-frequency waves are applied to generate plasma, and a high-frequency connector (not illustrated) connected to the end of the high-frequency electrode unit 140 to transmit high-frequency waves supplied from the high-frequency supply unit (not illustrated), and the high-frequency connector (not illustrated) may also be made of a molybdenum-tungsten alloy containing molybdenum (Mo) and tungsten (W) (located at (D) in FIG. 14).

That is, in the conventional substrate heating apparatus 300, the connecting member 340, a heating element connector (not illustrated), and a high-frequency connector (not illustrated) are typically made of a metal such as molybdenum (Mo) like the heating element, whereas the body 110 of the substrate heating apparatus 300 is typically made of ceramic such as aluminum nitride (AlN). In the process of manufacturing the substrate heating apparatus 300, the second connecting member 340, a heating element connector (not illustrated), and a high-frequency connector (not illustrated) are disposed at predetermined positions in a preform of the body 110 made of ceramic such as aluminum nitride together with the heating elements, and then the ceramic is sintered by applying high pressure in a high temperature environment (e.g., about 1,800 degrees C) to manufacture the substrate heating apparatus 300.

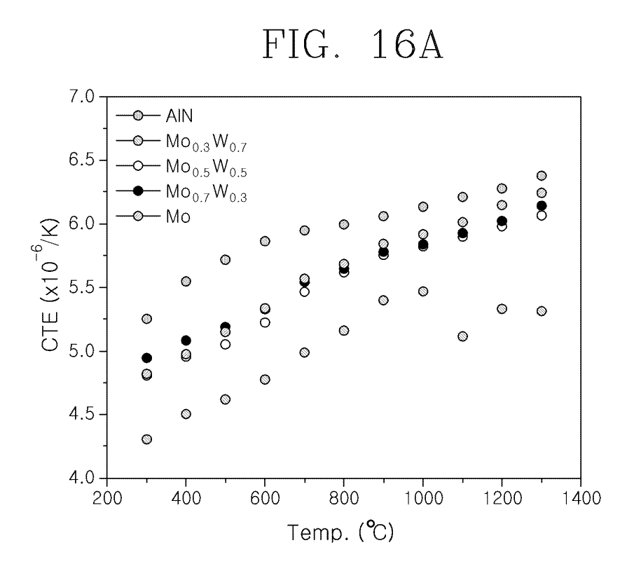

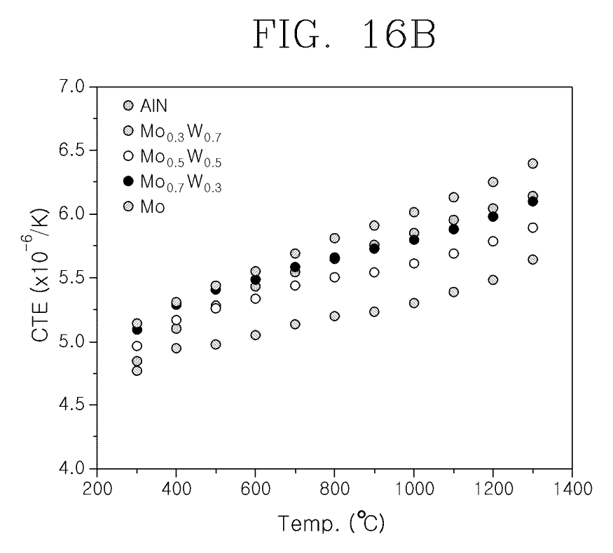

However, in the sintering process, while high pressure is applied in a high temperature environment, fine cracks may occur in the ceramic region around the connecting member 340 in the body 110 (e.g., see cracks around the connecting member 340 in FIG. 15) due to thermal stress generated due to a difference in coefficient of thermal expansion (CTE) between the ceramic forming the body 110 and the metal materials of the connecting member 340, the heating element connector (not illustrated), and the high-frequency connector (not illustrated).

Furthermore, as exposure to the process temperature (e.g., 650 degrees C) of the substrate heating apparatus 300 is accumulated, the fine cracks spread, which may lead to deterioration of durability of the substrate heating apparatus 300 and shortening of the service life of the substrate heating apparatus 300.

In this regard, in the substrate heating apparatus 300 according to an embodiment of the present disclosure, since the connecting member 340, the heating element connector (not illustrated), or the high-frequency connector (not illustrated) is made of a molybdenum-tungsten alloy containing molybdenum and tungsten, it is possible to effectively suppress the occurrence of fine cracks by preventing the generation of thermal stress due to a difference in coefficient of thermal expansion (CTE) with the ceramic material such as aluminum nitride (AlN) constituting the body 110.

As a specific example, in the body 110 of the substrate heating apparatus 300 according to an embodiment of the present disclosure, the heating unit 130 and the high-frequency electrode unit 140 may be embedded in the ceramic sintered compact (not illustrated) of the body 110, wherein the heating element connector (not illustrated) is disposed at a position where the heating element connector is connected to the heating unit 130 to transmit power to the heating unit 130.

In this case, in the substrate heating apparatus 300 according to an embodiment of the present disclosure, since the heating element connector (not illustrated) is made of a molybdenum-tungsten alloy containing molybdenum and tungsten, the generation of thermal stress due to the difference in coefficient of thermal expansion (CTE) with the ceramic material such as (AlN) constituting the body 110 is prevented, so that the occurrence of fine cracks is suppressed.

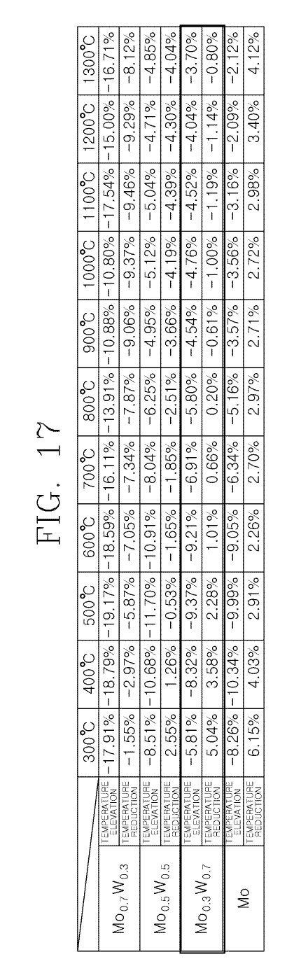

More specifically, FIGS. 16A to 16B show the thermal expansion coefficients of metal materials (molybdenum, molybdenum-tungsten alloy) constituting the heating element connector (not illustrated) and the ceramic material (AlN) in comparison (FIG. 16A: Temperature Elevation CTE, FIG. 16B: Temperature Reduction CTE).

FIG. 17 is a table showing numerical differences in thermal expansion coefficients of metal materials (molybdenum, molybdenum-tungsten alloy) constituting the heating element connector (not illustrated) with reference to the thermal expansion coefficient of the ceramic material.

Referring to FIGS. 16A to 16B and FIG. 17, when compared to the coefficient of thermal expansion (H65) of the ceramic material, it can be seen that the coefficient of thermal expansion of the molybdenum 70% - tungsten 30% alloy (Mo_{0.7}W_{0.3}) is closest to that of the ceramic material, and the coefficient of thermal expansion of the molybdenum 50% - tungsten 50% alloy (Mo_{0.5}W_{0.5}) also has a value close to that of the ceramic material, whereas the difference in the coefficients of thermal expansion between the molybdenum 30% - tungsten 70% alloy (Mo_{0.3}W_{0.7}) and the ceramic material may be greater than that between the molybdenum 100% (Mo) and the ceramic material.

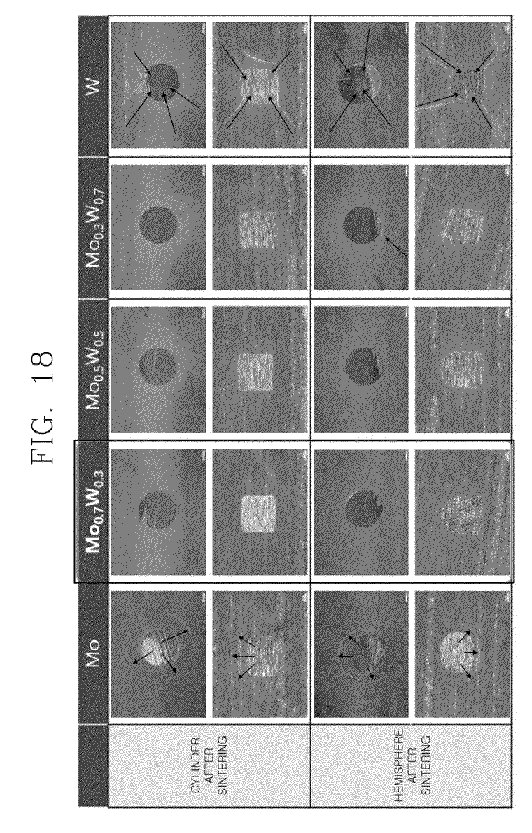

In this regard, FIG. 18 exemplifies experimental results concerning occurrence of fine cracks according to types of metal materials (molybdenum, molybdenum-tungsten alloy, tungsten) constituting heating element connectors (not illustrated).

First, the heating element connectors are classified into a cylindrical shape and a shape with a hemisphere added to an end thereof, and for each shape, the heating element connectors were made by using molybdenum (Mo), molybdenum-tungsten alloys (Mo_{0.3}W_{0.7}, Mo_{0.5}W_{0.5}, and Mo_{0.7}W_{0.3}), and tungsten (W). Accordingly, FIG. 18 shows the results for confirming whether fine cracks occurred in the ceramic sintered compacts after the sintering process.

As can be seen in FIG. 18, when the heating element connector is made of molybdenum (Mo) or tungsten (W), it can be confirmed that a number of fine cracks occurred in the ceramic sintered compact.

In addition, the heating element connector is made of the molybdenum 30% - tungsten 70% alloy (Mo_{0.3}W_{0.7}), it can be confirmed that some fine cracks occurred in the ceramic sintered compact.

In contrast, when the heating element connectors are made of the molybdenum 70% - tungsten 30% alloy (Mo_{0.7}W_{0.3}) and the molybdenum 50% - tungsten 50% alloy (Mo_{0.5}W_{0.5}), it can be seen that fine cracks did not occur in the ceramic sintered compacts.

Therefore, in the substrate heating apparatus 300 according to an embodiment of the present disclosure, the heating element connector is preferably made of a molybdenum-tungsten alloy containing molybdenum and tungsten. Furthermore, it was confirmed that when the molybdenum-tungsten alloy contains molybdenum in a proportion of 40% to 80% and tungsten in a proportion of 20% to 60%, it is possible to effectively prevent the occurrence of fine cracks in the ceramic sintered compacts of the bodies 110 even when the ceramic sintered compacts are subjected to a high-temperature and high-pressure sintering process.

Although the present disclosure has been described mainly with reference to the heating element connector as an example, the present disclosure is not limited thereto. As described above, not only the high-frequency connector (not illustrated) and the connecting member 340, but also the first heating element 310, the second heating element 320, the third heating element 330, or the high-frequency electrode unit 140, which were typically made of molybdenum in the related art, may also be made of a molybdenum-tungsten alloy containing molybdenum and tungsten. Furthermore, when the molybdenum-tungsten alloy contains molybdenum in a proportion of 40% to 80% and tungsten in a ratio of 20% to 60%, it is possible to effectively prevent the occurrence of fine cracks in a ceramic sintered compact of the body 110 even when the body 110 is subjected to a high-temperature and high-pressure sintering process.

Furthermore, in the substrate heating apparatus 300 according to an embodiment of the present disclosure, when the connecting member 340, the heating element connector (not illustrated), or the high-frequency connector (not illustrated) is made of a molybdenum-tungsten alloy containing molybdenum (Mo) and tungsten (W), the connecting member 340, the heating element connector, or the high-frequency connector is preferably subjected to a heat treatment process including an annealing process.

That is, when the connecting member 340, the heating element connector, or the high-frequency connector is made of a molybdenum-tungsten alloy, cracks may occur in the molybdenum-tungsten alloy in a machining process, a pressing process for press-fitting the heating element into an opening, or the like due to the brittleness of tungsten.

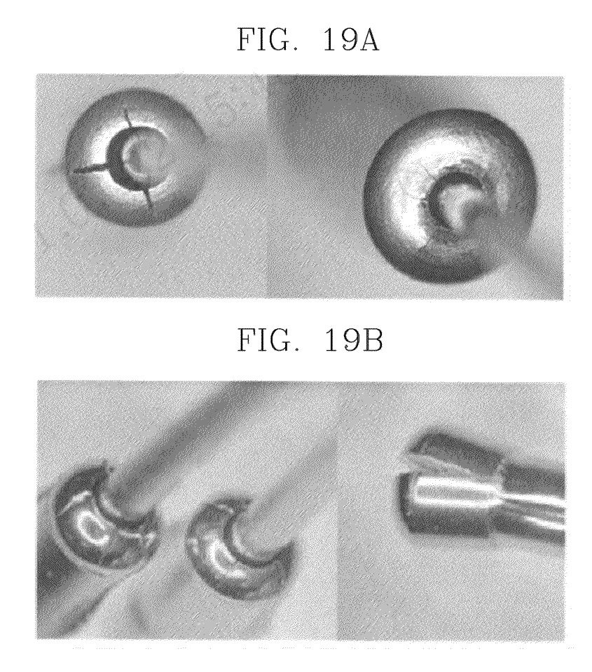

As a more specific example, FIGS. 19A and 19B exemplify the cases in which cracks occurred in the connecting members 340 during a machining process and a pressing process when the connecting members 340 were made of a molybdenum-tungsten alloy.

In this regard, in the substrate heating apparatus 300 according to an embodiment of the present disclosure, when the connecting member 340, the heating element connector, or the high-frequency connector is made of a molybdenum-tungsten alloy, the connecting member 340, the heating element connector, or the high-frequency connector is subjected to a heat treatment process including an annealing process. As a result, it is possible to improve the ductility of the molybdenum-tungsten alloy by removing the internal cracks of the hardened molybdenum-tungsten alloy and refining the crystal grains of the molybdenum-tungsten alloy.

In this case, the annealing process is preferably performed in consideration of the recrystallization temperature of the material of the substrate heating apparatus 300 according to an embodiment of the present disclosure. In particular, the substrate heating apparatus 300 according to an embodiment of the present disclosure is preferably subjected to the annealing process at a temperature selected within the range between the recrystallization temperature of molybdenum and the recrystallization temperature of tungsten.

More specifically, for a molybdenum-tungsten alloy, the substrate heating apparatus 300 according to an embodiment of the present disclosure is preferably subjected to the annealing process at a temperature within the range between the recrystallization temperature of molybdenum (900 degrees C) and the recrystallization temperature of tungsten (1,000 to 1,300 degrees C). When an appropriate temperature is exceeded, crystal grains grow and become more brittle rather than ductile, increasing the risk of cracking in the molybdenum-tungsten alloy during a machining process and a pressing process.

Furthermore, the annealing process for the substrate heating apparatus 300 according to an embodiment of the present disclosure may include a rapid cooling process that rapidly cools the connecting member 340, the heating element connector, or the high-frequency connector in a temperature range in which a sigma phase is generated in the molybdenum.

That is, in the case of molybdenum, a sigma phase may be generated in the temperature range of about 700 to 900 degrees C during cooling, and thus the machinability and ductility of the molybdenum-tungsten alloy may be deteriorated. Thus, it is preferable to rapidly cooling the molybdenum from the above temperature section to suppress the formation of the sigma phase.

As a more specific example, after the annealing process is performed at about 1,250 degrees C for the substrate heating apparatus 300 according to an embodiment of the present disclosure, a heat treatment process for the connecting member 340, the heating element connector, or the high-frequency connector may be performed in a manner of performing a rapid cooling process from 900 degrees C.

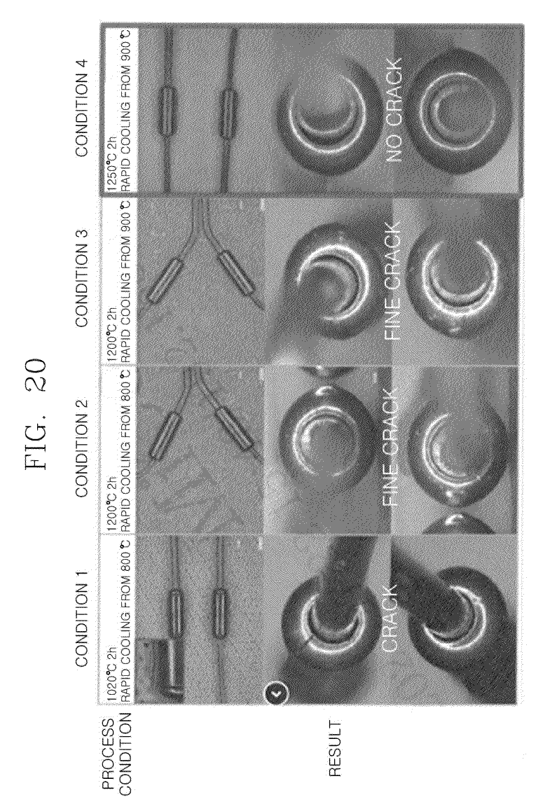

FIG. 20 exemplifies more specifically the results of a crack generation experiment for the connecting member 340 according to heat treatment performed under various conditions.

As can be seen in FIG. 20, in the case of Condition 1 (after an annealing process at 1,020 degrees C for 2 hours, rapid cooling was performed from 800 degrees C by using nitrogen (N₂) such as gaseous nitrogen or liquid nitrogen), it can be seen that cracks are clearly observed in the connecting member 340.

In the case of Condition 2 (after an annealing process at 1,200 degrees C for 2 hours, rapid cooling was performed from 800 degrees C by using liquid nitrogen (N₂)) and Condition 3 (after an annealing process at 1,200 degrees C for 2 hours, rapid cooling was performed from 900 degrees C by using liquid nitrogen (N₂)), fine cracks are observed in the connecting member 340. Thus, it can be seen that, even though the degree of cracking is lowered, cracks still occurs.

In contrast, in the case of Condition 4 (after an annealing process at 1,250 degrees C for 2 hours, rapid cooling was performed from 900 degrees C by using nitrogen (N₂) such as gaseous nitrogen or liquid), no cracks are observed at all. Thus, it can be seen that the ductility of the molybdenum-tungsten alloy is improved and workability is secured through the heat treatment process.

Accordingly, in the substrate heating apparatus 300 according to an embodiment of the present disclosure, it is possible to prevent the occurrence of fine cracks in the ceramic material of the body 110 by suppressing the generation of thermal stress due to the difference in thermal expansion coefficient between the metal materials of the connecting member 340 or the like and the ceramic material of the body 110 and the generation of compressive stress by applied high pressure in the sintering process or the like in which high temperature and high pressure are applied in the process of manufacturing the substrate heating apparatus 300. Furthermore, it is possible to effectively prevent deterioration of durability and shortening of the service life of the substrate heating apparatus 300.

In the above description, the present disclosure has been described mainly with reference to the connecting member 340 as an example, but the present disclosure is not limited thereto. As described above, in addition to a heating element connector (not illustrated) and a high-frequency connector (not illustrated), the first heating element 310, the second heating element 320, the third heating element 330, or the high-frequency electrode unit 140 may also be made of a molybdenum-tungsten alloy containing molybdenum and tungsten and may be subjected to a heat treatment process including an annealing process. In addition, by performing the annealing process at a temperature selected within the range between the recrystallization temperature of molybdenum and the recrystallization temperature of tungsten, and making the heat treatment process include a rapid cooling process of rapid cooling the first heating element 310, the second heating element 320, the third heating element 330, or the high-frequency electrode unit 140 in a temperature range in which a sigma phase is generated in the molybdenum, it is possible to improve the ductility of the molybdenum-tungsten alloy and secure the workability of the molybdenum-tungsten alloy.

The forgoing description merely illustratively describes the technical idea of the present disclosure, and various changes and modifications may be made by a person ordinarily skilled in the art without departing from the essential characteristics of the present disclosure. Accordingly, the embodiments described in the present disclosure are provided not to limit, but to explain the technical spirit of the present disclosure, and the disclosure is not limited to these embodiments. The protection scope of the present disclosure should be interpreted based on the following claims, and all technical ideas within the scope of equivalents thereof should be construed as being included in the scope of the present disclosure.

What is claimed is:

1. A substrate heating apparatus for heating a substrate, the substrate heating apparatus comprising:
a body including a substrate seating portion on which the substrate is seated, to support the substrate;
a first heating element located in an inner region of the body;
a second heating element located in an outer region surrounding the inner region;
a third heating element configured to transmit current to the second heating element across the inner region of the body; and
a connecting member electrically interconnecting the second heating element and the third heating element,
wherein the third heating element is made of a molybdenum-tungsten alloy containing molybdenum in a proportion of 40 to 80% and tungsten in a proportion of 20 to 60%.

2. The substrate heating apparatus of claim 1, wherein the connecting member is implemented in a partially spherical shape obtained by removing, from a spherical shape, a portion below a first plane spaced apart by a predetermined distance downward from a center point of the spherical shape, and the first plane is disposed in parallel to the substrate seating portion.

3. The substrate heating apparatus of claim 1, wherein the connecting member is implemented in a oval shape obtained by vertically contracting a spherical shape, and is disposed such that a vertical axis of the oval shape is perpendicular to the substrate seating portion.

4. The substrate heating apparatus of claim 1, wherein the connecting member is implemented in a cylindrical shape, and is disposed such that a longitudinal axis of the cylindrical shape is perpendicular to the substrate seating portion, and
openings into which the second heating element and the third heating element are fixedly inserted, respectively, are vertically provided in a side portion of the cylindrical shape in a direction perpendicular to the longitudinal axis.

5. The substrate heating apparatus of claim 1, wherein the connecting member is implemented in a cylindrical shape, and is disposed such that a longitudinal axis of the cylindrical shape is parallel to the substrate seating portion, and
openings into which the second heating element and the third heating element are fixedly inserted, respectively, are provided in opposite flat surfaces of the cylindrical shape to face each other.

6. The substrate heating apparatus of claim 1, wherein at least one of the first heating element, the second heating element and the connecting member is made of molybdenum-tungsten alloy containing molybdenum and tungsten.

7. The substrate heating apparatus of claim 1, wherein at least one of the first heating element, the second heating element and the connecting member is made of molybdenum-tungsten alloy containing molybdenum in a proportion of 40% to 80% and tungsten in a proportion of 20% to 60%.

8. The substrate heating apparatus of claim 1, wherein the connecting member is subjected to a heat treatment process including an annealing process.

9. The substrate heating apparatus of claim 8, wherein the annealing process is performed at a temperature selected within a range between recrystallization temperature of molybdenum and recrystallization temperature of tungsten.

10. The substrate heating apparatus of claim 8, wherein the heat treatment process includes a rapid cooling process of rapidly cooling the connecting member in a temperature range in which a sigma phase is generated in the molybdenum.

11. The substrate heating apparatus of claim 1, further comprising:
a heating element connector connected to an end of the first heating element to transmit power supplied from a power supply,
wherein the heating element connector is made of a molybdenum-tungsten alloy containing molybdenum and tungsten.

12. The substrate heating apparatus of claim 11, wherein the heating element connector is made of molybdenum-tungsten alloy containing molybdenum and tungsten.

13. The substrate heating apparatus of claim 11, wherein the heating element connector is made of molybdenum-tungsten alloy containing molybdenum in a proportion of 40% to 80% and tungsten in a proportion of 20% to 60%.

14. The substrate heating apparatus of claim 1, further comprising:
a high-frequency electrode unit to which high-frequency waves are applied to generate plasma; and
a high-frequency connector connected to an end of the high-frequency electrode unit to transmit high-frequency waves supplied from a high-frequency wave supply unit,
wherein at least one of the high-frequency electrode unit and the high-frequency connector is made of a molybdenum-tungsten alloy containing molybdenum and tungsten.

15. The substrate heating apparatus of claim 14, wherein at least one of the high-frequency electrode unit and the high-frequency connector is made of molybdenum-tungsten alloy contains molybdenum in a proportion of 40 to 80% and tungsten in a proportion of 20 to 60%.
